(19) United States
(12) Patent Application Publication
(10) Pub. No.: US 2012/0016608 A1
(43) Pub. Date: Jan. 19, 2012

(54) METHOD AND SYSTEM FOR MONITORING RESIDENTIAL APPLIANCES

(75) Inventors: LEE-CHUN KO, New Taipei City (TW); CHIH-YUAN LIU, Hsinchu County (TW); LUN-CHIA KUO, Taichung City (TW); JUI-HUA TAN, Tainan City (TW)

(73) Assignee: Industrial Technology Research Institute, Hsinchu (TW)

(21) Appl. No.: 13/183,923

(22) Filed: Jul. 15, 2011

Related U.S. Application Data
(60) Provisional application No. 61/364,886, filed on Jul. 16, 2010.

(30) Foreign Application Priority Data
May 13, 2011 (TW) 100116823

(51) Int. Cl. G06F 19/00; G01R 27/00

(52) U.S. Cl. 702/62; 702/65

(57) ABSTRACT

This present disclosure provides a method and the system thereof for monitoring residential appliances, which includes: measuring electrical data in a residence and transmitting the electrical data to a local data-processing unit, the electrical data at least containing a voltage, a real power, and a reactive power; normalizing the electrical data according to the voltage; calculating a variation of the normalized electrical data when the electrical data change; and comparing the variation of the normalized electrical data to an electrical feature which is contained in appliance information of the local data-processing unit, so as to determine the appliance which causes the variation of the electrical data.

### TECHNICAL FIELD

The present disclosure relates to a method and a system for monitoring residential appliances.

### BACKGROUND

Due to the technological trend of “Energy Efficiency and Carbon Reduction”, the states have made a lot of efforts to decrease the possibility of pollution, to increase the usage efficiency of energy, and to educate people the importance of environmental protection. Recently, the advances of technology have been focused on the purpose of “Energy Efficiency and Carbon Reduction” intensely, such as building up the Smart Grid, developing energy-efficient electric vehicles, and improving the Solar Power. However, except for the promotion of the government policies, if people can cultivate a good habit of electric usage, such as turning off an appliance conveniently and diminishing the use of high power-consumption products, the unnecessary consumption of energy and cost of expense can be saved and accumulated. Moreover, it is reported that people can save 5% to 15% cost of electricity bill if they have ideas about the information of their household electricity.

Although the foregoing report provides people information to save more electrical energy, if the appliance users know which appliance is over-used to be the main cause for their electricity bill, it is possible to save the energy further. For example, if the electricity bill can tell users electricity usage of each appliance in their residence, including the statistical use data and charts of each appliance, they can realize which appliance causes the main electric consumption and thus adjust their habit of electric usage so as to save the energy further.

To measure the operational conditions of each appliance in the residence without changing composition of the appliance itself, a digital power meter can simply be coupled to the electrical lines connected to each appliance. The measured data can then be transmitted to a managing server in wireless or by the power-line communication, so that the server can collect and analyze statistically to satisfy the requirement. Nevertheless, a powermeter for each appliance which is required to be detected can lead to a quite high cost of addition for a household. Moreover, too many powermeters in an appliance system may cause the possibility of wrong measurement. Therefore, it is in need of a measuring system of residential appliances, so that operational conditions of each particular appliance in the residence can be known by its user in a low-cost way, through the management system provided by the utility provider or the residence, so as to achieve the goals of “Energy Efficiency and Carbon Reduction”.

### SUMMARY

According to one aspect of the present disclosure, a first embodiment provides a method for monitoring residential appliances, the method including the following steps: measuring electrical data in a residence and transmitting the electrical data to a local data-processing unit, the electrical data at least containing a voltage, a real power, and a reactive power; normalizing the electrical data according to the voltage; calculating a variation of the normalized electrical data when the electrical data change; comparing the variation of the normalized electrical data to an electrical feature which is contained in appliance information of the local data-processing unit, so as to determine the appliance which causes the variation of the electrical data; if the variation of the normalized electrical data is matched with the electrical feature of one of the residential appliances, confirming that the variation is caused by a change of operational status in the one of the residential appliances; otherwise, transmitting the variation of the normalized electrical data to a remote data-processing unit to be further compared to an electrical feature which is contained in appliance information of the remote data-processing unit; and transmitting the comparison result of the remote data-processing unit to the local data-processing unit to renew the electrical features of the residential appliances recorded in the local data-processing unit.

According to another aspect of the present disclosure, a second embodiment provides a system for monitoring residential appliances, the system including: a measuring unit provided for measuring electrical data in a residence; a local data-processing unit connected to the measuring unit, comprising a first database for recording appliance information of at least one residential appliance, and provided for normalizing the electrical data, computing a variation of the normalized electrical data, and comparing the variation of the normalized electrical data to an electrical feature which is contained in the appliance information of the first database, so as to determine the appliance which causes the variation of the electrical data; and a remote data-processing unit connected to the local data-processing unit, comprising a second database for recording appliance information of various residential appliances with a possibility of being used, and provided for comparing the variation the normalized electrical data to an electrical feature which is contained in the appliance information of the second database.

According to another aspect of the present disclosure, a third embodiment provides a method for monitoring residential appliances, the method including the following steps: providing a smart meter, which at least has functions of data processing, database, and displaying; measuring electrical data in a residence, the electrical data at least containing a voltage, a real power, and a reactive power; normalizing the electrical data according to the voltage; calculating a variation of the normalized electrical data when the electrical data change; and comparing the variation of the normalized electrical data to an electrical feature which is contained in appliance information of the smart meter, so as to determine the appliance which causes the variation of the electrical data.

According to another aspect of the present disclosure, a fourth embodiment provides a method for monitoring residential appliances, the method including the following steps: measuring electrical data in a residence and transmitting the electrical data to a remote data-processing unit, the electrical data at least containing a voltage, a real power, and a reactive power; normalizing the electrical data according to the voltage; calculating a variation of the normalized electrical data when the electrical data change; comparing the variation of the normalized electrical data to an electrical feature which is contained in appliance information of the remote data-processing unit, so as to determine the appliance which causes the variation of the electrical data; and transmitting the comparison result of the remote data-processing unit to a local display.

According to another aspect of the present disclosure, a fifth embodiment provides a system for monitoring residential appliances, the system including: a measuring unit provided for measuring electrical data in a residence; and a remote data-processing unit connected to the measuring unit, comprising a second database for recording appliance information of at least one residential appliance, and provided for normalizing the electrical data, computing a variation of the normalized electrical data, and comparing the variation of the normalized electrical data to an electrical feature which is contained in the appliance information of the second database, so as to determine the appliance which causes the variation of the electrical data.

According to another aspect of the present disclosure, another embodiment provides an apparatus for monitoring residential appliances, the apparatus including: a socket module provided for supplying at least one appliance with a power source; a measuring module measuring electrical data of the socket module; a data transmitter wirelessly transmitting the electrical data measured by the measuring module; a database recording appliance information of the at least one appliance; and a display unit displaying the electrical data measured by the measuring module.

Further scope of applicability of the present application will become more apparent from the detailed description given hereinafter. However, it should be understood that the detailed description and specific examples, while indicating exemplary embodiments of the disclosure, are given by way of illustration only, since various changes and modifications within the spirit and scope of the disclosure will become apparent to those skilled in the art from this detailed description.

### BRIEF DESCRIPTION OF THE DRAWINGS

The present disclosure will become more fully understood from the detailed description given herein below and the accompanying drawings which are given by way of illustration only, and thus are not limitative of the present disclosure and wherein:

FIG. 1 is a graph illustrating the dependence of real power of an appliance in use on the operation time.

FIG. 2 is a power distribution graph of several commonly used appliances.

FIG. 3 is a graph illustrating harmonic currents of an appliance in various odd orders, before and after the appliance is turned on.

FIG. 4 is a graph of the transient real power after an appliance is turned on.

FIG. 5 is a schematic flowchart showing the procedure of a method for monitoring residential appliances according to a first embodiment of the present disclosure.

FIG. 6 is a block diagram showing a system for monitoring residential appliances according to a second embodiment of the present disclosure.

FIG. 7 is a block diagram showing an apparatus for monitoring residential appliances according to an embodiment of the present disclosure.

FIG. 8 is a block diagram showing an apparatus for monitoring residential appliances with a plurality of socket units and measuring units according to another embodiment of the present disclosure.

FIG. 9 is a graph showing the connection between the measuring module in FIG. 7 and the power lines in a first way.

FIG. 10 is a graph showing the connection between the measuring module in FIG. 7 and the power lines in a second way.

FIG. 11 is a graph showing the connection between the measuring module in FIG. 7 and the power lines in a third way.

FIG. 12 is a graph showing the connection between the measuring module in FIG. 7 and the power lines in a fourth way.

FIG. 13 is a schematic flowchart showing the procedure of a method for monitoring residential appliances according to a third embodiment of the present disclosure.

FIG. 14 is a schematic flowchart showing the procedure of a method for monitoring residential appliances according to a fourth embodiment of the present disclosure.

FIG. 15 is a block diagram showing a system for monitoring residential appliances according to a second embodiment of the present disclosure.

### DESCRIPTION OF THE EXEMPLARY EMBODIMENTS

For further understanding and recognizing the fulfilled functions and structural characteristics of the disclosure, several exemplary embodiments cooperating with detailed description are presented as the following.

Electricity usage information which includes electrical parameters in a residence can be measured by a powermeter, a smart meter, or the like. The measured electrical parameters can be calibrated or normalized according the practical voltage. On the other hand, a change of electrical parameter values due to turning on or off of an appliance can be regarded as its electrical feature, which can be compared with appliance information recorded in a database of a local-end system, so as to see if any appliance information is matched. If there is no match between the electrical feature and the appliance information (for example, the appliance is new for the database), the local-end system may transmit the electrical feature to a remote-end server or a cloud server for a more complete comparison. The comparison result is then transmitted back to the local-end system to renew the appliance information recorded in the local-end database, so that if the same appliance is turned on again, it can take part in the comparison according to the appliance information of the database. In the present disclosure, the terms “local-end” and “remote-end” are defined basically according to a distance between the system and the residence to be measured. The local-end system can be a household personal computer (PC) or a smart meter, while the remote-end system may be a cloud server or the like. The electrical feature plays a key role in this disclosure, so it is described first in the following paragraphs.

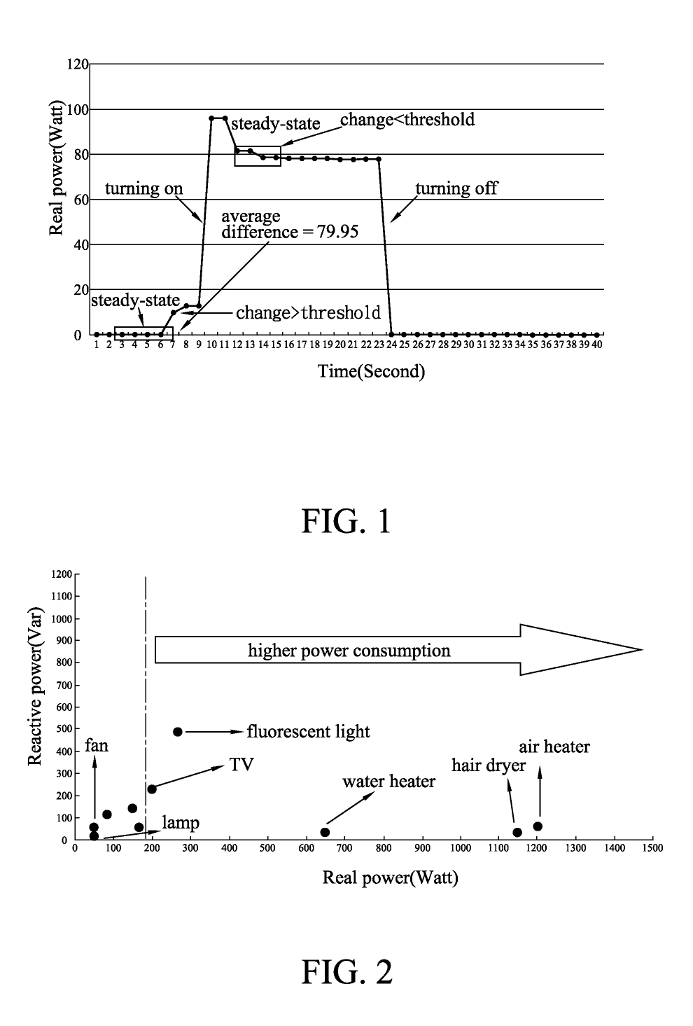

The computational analysis of electrical feature may be classified into steady-state and transient analyses. In the steady-state way, the differences of electric power, including real and reactive powers, before and after the appliance is turned on or off can be used as their electrical features. FIG. 1 shows the dependence of real power (in watt) of an appliance in use on the operation time (in second). In the beginning, after the change of the real power curve is more than a predetermined threshold, the appliance is regarded as being turned on or off (an increasing curve indicates turning on while a decreasing curve indicates turning off). If there is no another change more than the threshold happened to the curve, the appliance is regarded as being in its steady state. The consumed power can then be calculated by subtracting the average real power of this steady state by that of the last-time steady state. For example, the appliance in FIG. 1 consumes a real power of about 80 watts, so that the appliance information with about 80 watts real power can be matched as the appliance which is turned on. The threshold and the steady-state duration can be predetermined according to appliance types and its operating voltage level. A reasonable threshold may be less than 10% and a reasonable steady-state duration may be in the range of 2-3 seconds.

Furthermore, since various appliances may consume almost the same real power so that the identification of the turned on or off appliance may fail, it may be not enough to identify the turned on or off appliance just based on the real power. Particularly, a non-resistive appliance may consume a reactive power, which can be used as another electrical feature parameter. A reactive power consumed by an appliance can be measured by a smart meter or a powermeter, or computed by the equations: Q=\sqrt{S²−P²} and S=V×I, where S, P, Q, V, and I denote apparent power, real power, reactive power, voltage, and current of the appliance, respectively. In our experience, the combination of the two foregoing electrical parameters, real power and reactive power, is sufficient to discriminate most of the household appliances. FIG. 2 illustrates a power distribution graph of several commonly used appliances, wherein the x axis is in real power and the y axis is in reactive power. As can be seen in FIG. 2, most appliances have different electrical features from each other. If the feature points of various appliances are not located at the same place, misjudgment may not occur according to FIG. 2. It can be noted that the feature points of small-power appliances, having small real and reactive powers, may be located in the left lower part of the figure. For example, for the appliances with a real power less than 40 watts and a reactive power less than 30 vars, these small appliances are not much concerned by users and are not what this disclosure mainly focuses on; therefore, they can be neglected here.

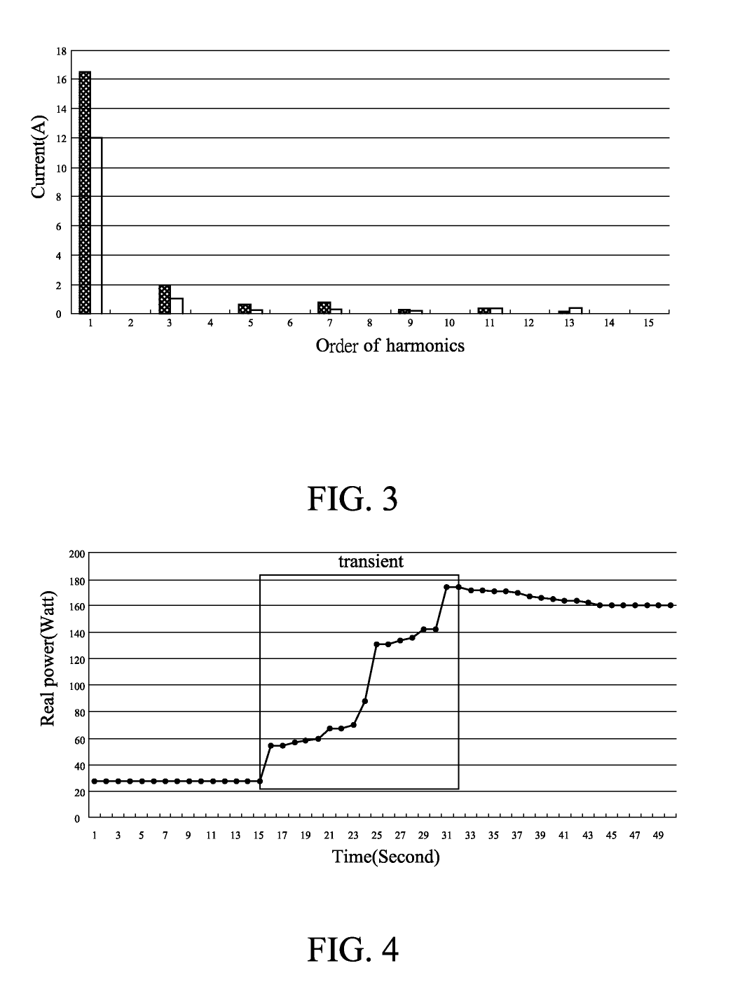

A measuring unit of high sampling rate can be used to measure a harmonic current change due the operation status change of an appliance. The harmonic current change can also be included in the electrical features of the appliance. Considering the appliances of motor mode, pump mode, electronic product mode, and fluorescent light mode, their harmonic currents of odd order may be remarkable to be used as electrical features of the appliances. To compute the harmonic currents, the measured current is transformed from its time domain to its frequency domain by the fast Fourier transformation (FFT) method. For example, FIG. 3 illustrates harmonic currents of an appliance in various odd orders, before and after the appliance is turned on, wherein the x axis is in order of the harmonic currents, the y axis is in current (A), the reticular bars denotes the harmonic current before the appliance is turned on, and the filled bars denotes the harmonic current after the appliance is turned on. Whereby, the changes in the harmonic currents of odd order may be used to discriminate the appliance which causes the change of operational status.

In the transient way, the transient changes in the electrical parameters may be used as electrical features to discriminate the appliance which causes the change of operational status. Since the change is transient, the measuring apparatus have to be with a high sampling rate. FIG. 4 shows a graph of the transient real power after an appliance is turned on. If the change of electrical parameters of an appliance at turning on or off is constant and reproducible, the transient signals or waveforms can be used as electrical features of the appliance, so as to discriminate the operational status of an appliance.

According to the above description, to get the operational status of a household appliance according to the electrical features thereof, one can first compare the changes of the measured real and reactive powers. If the comparison fails, the change of harmonic currents of odd order can be included for further comparison. If the comparison still fails, the transient analysis of the electrical parameters can also be included for further comparison. The sequence of the electrical features to be compared is not limited in this disclosure. Wherein, the appliance information containing electrical features of each appliance is set into the database in a way that the appliance user measures electrical parameters of the appliance or the appliance manufacturer measures them before the appliance goes to the market. The appliance information may be recorded in a local data-processing unit, and also can be uploaded to a remote data-processing unit so as to be shared with the other users.

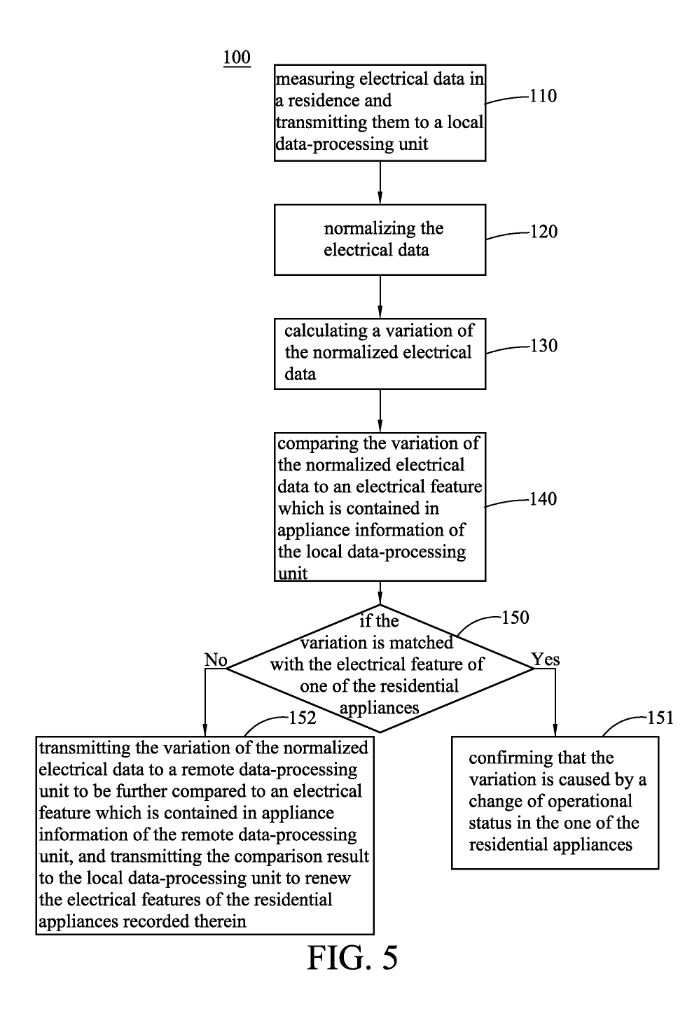

Regarding a measuring apparatus of fundamental function, a data-processing unit in the local end can be used to perform calibration of electric parameters, extraction of electric features, and operation of comparing the electric features. Please refer to FIG. 5, which is a schematic flowchart showing the procedure of a method 100 for monitoring residential appliances according to a first embodiment of the present disclosure. The method 100 comprises the following steps. In Step 110, electrical data in a residence is measured and then transmitted to a local data-processing unit. In Step 120, the electrical data are normalized. In Step 130, a variation of the normalized electrical data is calculated. In Step 140, the variation of the normalized electrical data is compared to an electrical feature which is contained in appliance information of the local data-processing unit. The succeeding step follows according to the comparison result in the Step 150, which matches the variation with the electrical features of the residential appliances. If the variation is matched with the electrical feature of one of the residential appliances, it is confirmed, in Step 151, that the variation is caused by a change of operational status in the one of the residential appliances. Otherwise, it goes to Step 152, in which the variation is transmitted to a remote data-processing unit to be further compared to an electrical feature which is contained in appliance information of the remote data-processing unit, and the comparison result is transmitted back to the local data-processing unit to renew the electrical features of the residential appliances recorded in the local data-processing unit.

According to the first embodiment, the Step 110 is to measure the electrical data including a voltage, a real power, and a reactive power used in the residence. The electrical data can then be transmitted to the local data-processing unit for the computation of electric features. Also, the electrical data can further comprise a harmonic current of odd order or a transient signal which is of current, real power, reactive power, or apparent power, so as to be applied to the steady-state and transient-state analysis of the electric features and the comparison in the succeeding procedures.

The Step 120 is to normalize the measured electrical data or parameters. The reason of the normalization is that the electrical data are measured based on the voltage level at a local area, but the voltage levels of residential power supply are non-uniform in various local areas, at different times, or for varied electric utilities; for example, the voltage levels are usually between 105 and 125 volts in the US. This leads to that the electrical data or parameters measured in different conditions can not be in accordance with each other. In case the electrical data can be normalized according to the measured local voltage at that time, then the normalized parameters can be applicable to various voltages of residential power due to different conditions of electric usage. For example, the normalized electrical data at a voltage of 115 volts can be comparable to that at a voltage of 125 volts. The real power P and the apparent power S measured at a voltage of 120 volts can be normalized to be

P_{Norm}=(120/V)^{aP}×P

S_{Norm}(120/V)^{aQ}×S

where P_{Norm} and S_{Norm} denote the normalized P and S, respectively, V denotes the measured voltage before the normalization, and aP and aQ denote the normalization indices of real and reactive power, respectively. Usually aP and aQ are selected as 2 in the prior art; however, according to this embodiment, aP can be different from aQ, and their preferable value is in the range from 0 to 3. Both aP and aQ can not be 2 at the same time, or a misjudgment may be caused therein.

The Step 130 is to calculate the variation of the normalized electrical data when the measured electrical data change. Since the calculated variation is going to be compared to the electrical features of residential appliances recorded in the system database, the appliance information in the database can includes a basic information and an electrical feature of each appliance. The basic information can be selected from the group consisting of a brand name, an appliance type, a model number, and an operating mode, or can be composed of more than one element in the group. The electrical feature can be selected from the group consisting of a voltage, a real power, a normalization index of real power aP, a reactive power, a normalization index of reactive power aQ, a harmonic current of odd order, and a transient feature, or can be composed of more than one element in the group consisting of the real power, the reactive power, the harmonic current of odd order, and the transient feature. Wherein, the harmonic current of odd order can be a first-order harmonic current, a third-order harmonic current, or a fifth-order harmonic current, while the transient feature includes a transient waveform, a data type, a sampling rate, a sampling duration, and a sampling interval.

According to Step 140, the variation of the normalized electrical data is compared to the electrical feature which is contained in appliance information of the local data-processing unit, so as to determine the appliance which causes the variation of the electrical data. As described in Step 120, the preferable value of both aP and aQ fall in the range from 0 to 3. Here, the real power P and the reactive power Q can be normalized at a normalization voltage of 120 volts and according to a variety of aP and aQ; for example, aP and aQ can be respectively designated as the value in their preferable range and increase from 0 to 3 with an increase step of d. Then each normalized real power P and reactive power Q with different aP and aQ can be compared to the electrical feature of each appliance information in the database. If the variation of the normalized electrical data is matched with the electrical feature of one of the residential appliances, it is confirmed that the variation is caused by a change of operational status in the one of the residential appliances. For example, electrical data, a real power P and a reactive power Q, in a residence are measured at a certain real voltage V. Then, a normalization voltage of 120 volts and all possible aP and aQ (which increase from 0 to 3 with an increase step of d) are used to normalize the real power P and the reactive power Q into P, and Qₙ, respectively, as shown in the following.

<aP=0, P=P₀> <aQ=0, Q=Q₀>

<aP=d, P=P₁> <aQ=d, Q=Q₁>

<aP=2d, P=P₂> <aQ=2d, Q=Q₂>

. . .

<aP=nd, P=Pₙ> <aQ=nd, Q=Qₙ>

Regarding the appliances which can be operated in several levels of magnitude, the appliance information of each appliance further comprises an magnitude-level feature which is selected from the group consisting of an magnitude level, a voltage, a real power, a normalization index of real power, a reactive power, a normalization index of reactive power, a harmonic current of odd order, and a transient feature of each operating magnitude level, or can be composed of more than one element in the group; wherein the transient feature includes a transient waveform, a data type, a sampling rate, a sampling duration, and a sampling interval. After an appliance with several levels of magnitude is turned on and in use, it is a common behavior that people change its magnitude levels or switch its functional modes. Thus, when the measured electrical data change, the variation of the normalized electrical data can be compared to the difference of the magnitude-level features between the operating magnitude levels of the in-use appliance, before compared to the other electrical features of the appliance information. Whereby, the comparing operation can be speeded up further. The appliance information of each appliance in the residence is set either by its user when he begins to use it or by its manufacturer when it goes to the market in the local data-processing unit.

Then, the variation of the normalized electrical data is compared to the appliance information of the local data-processing unit one by one, so as to determine which appliance causes the variation of the electrical data. When the variation of the normalized real power and reactive power of the electrical data are respectively matched with the real power P at the same value aP and the reactive power Q at the same value aQ of one of the residential appliances, it is confirmed that the variation is caused by a change of operational status in the one of the residential appliances. Since it is inevitable that there is some possible error in the numerical computation, two thresholds T_{P} and T_{Q} are respectively assigned to the real and reactive powers as their computational tolerances. Considering the case of real power, if the difference between the normalized real power and the real power of the appliance information is more than 3 watts (wherein T_{P} is assumed to be 3), then their numerical values do not match to each other. After the foregoing process of comparison, if the variation of the normalized electrical data is matched with the electrical feature of one of the residential appliances, then it is confirmed that the variation is caused by a change of operational status in the one of the residential appliances; otherwise, it is regarded as that the comparison fails and the cause of the variation can not be attributed to the appliance information recorded in the local data-processing unit.

Hence, the succeeding step follows according to the comparison result in the Step 150, which tries to match the variation with the electrical features of the residential appliances. If the variation is matched with the electrical feature of one of the residential appliances, it is confirmed, in Step 151, that the variation is caused by a change of operational status in the one of the residential appliances. Otherwise, it goes to Step 152, in which the variation is transmitted to the remote data-processing unit to be further compared to an electrical feature which is contained in appliance information of the remote data-processing unit, and the comparison result is transmitted back to the local data-processing unit to renew the electrical features of the residential appliances recorded in the local data-processing unit. The appliance information recorded in the remote data-processing unit is set by a user or manufacturer of the residential appliances. The remote data-processing unit may store appliance information of various appliances, each of which may be produced by more than one manufacturer with different electrical features. The appliance information of each appliance is set in a way that the manufacturer of the residential appliances uploads the appliance information to the remote data-processing unit, or that the remote data-processing unit asks the manufacturer to provide the appliance information. Moreover, the change of operational status in the residential appliances is selected from the group consisting of turning on, turning off, magnitude-level switching, and function switching, which should be considered in the analysis of the electrical features of appliance. The electrical features in the appliance information can be further classified into groups according to an appliance attribution such as a resistance mode, a motor mode, a pump mode, an electronic product mode, and a fluorescent light mode. Various modes of appliance have their particular electrical features, respectively. To reduce the load of comparing with the appliance information in the whole database, if the mode or type of the possible causer appliance can be predicted, only the part of the database is needed to be compared one by one. Whereby, the comparing work can be speeded up further.

Furthermore, to update the electrical feature contained in appliance information of the database in the data-processing unit in real time so as to increase the accuracy of the comparing work, the embodiment can further perform computing a time weighted average of the electrical features of the appliance, and updating the appliance information in the local and remote data-processing units with the time weighted average. Wherein, the appliance information may further include a predetermined threshold which is used to determine whether the appliance is of aging deterioration. For example, if the predetermined threshold is not substantially equal to the electrical feature corresponding to the deviation of the electrical data, it can be thought that performance of the appliance has been aged or deteriorated. Also, according to the embodiment, power consumption curves of the appliance at different operating voltages may be computed by the local or remote data-processing unit, normalized based on the foregoing description about the normalization process, and then recorded in the data-processing unit.

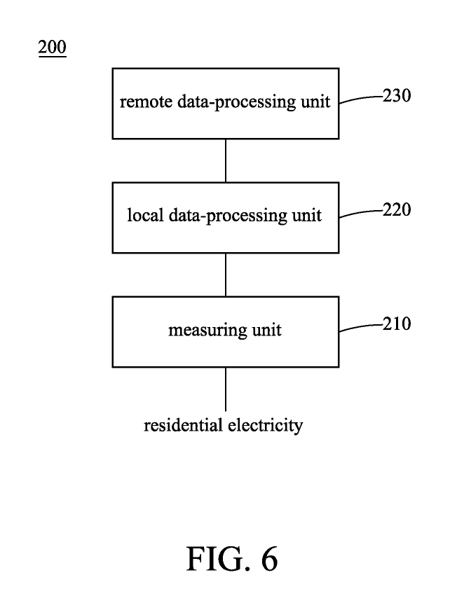

The foregoing method for monitoring residential appliances according to the first embodiment can be implemented in the following embodiment. Please refer to FIG. 6, which is a block diagram showing a system for monitoring residential appliances according to a second embodiment of the present disclosure. The system 200 includes a measuring unit 210, a local data-processing unit 220, and a remote data-processing unit 230. The measuring unit 210, used to measure electrical data in a residence, can be a power meter or a digital meter equipped therein. The measured electrical data may be then be uploaded to the local data-processing unit 220. According to this embodiment, the electrical data of a whole residence are measured in order to identify the causer appliance which switches its status of operation, and to further estimate its usage duration and cost, which was implemented by providing every single appliance with a measuring unit or a power meter in the prior art. In this embodiment, however, the measured electrical data can be compared with the electrical features of the appliances in the back-end data processing unit, so as to determine the causer appliance and get its usage condition and electrical data automatically in real time. The foregoing electrical data are mainly composed of a voltage, a real power, and a reactive power, so that they can be normalized and compared to the electrical features of the appliances according to the measured voltage in a first stage. If the comparison fails, the electrical data can include a harmonic current of odd order for further comparison to the appliance features in a second stage. If the comparison still fails, the electrical data can also include a transient signal, which may be of current, real power, reactive power, or apparent power, for further comparison to the appliance features in a third stage.

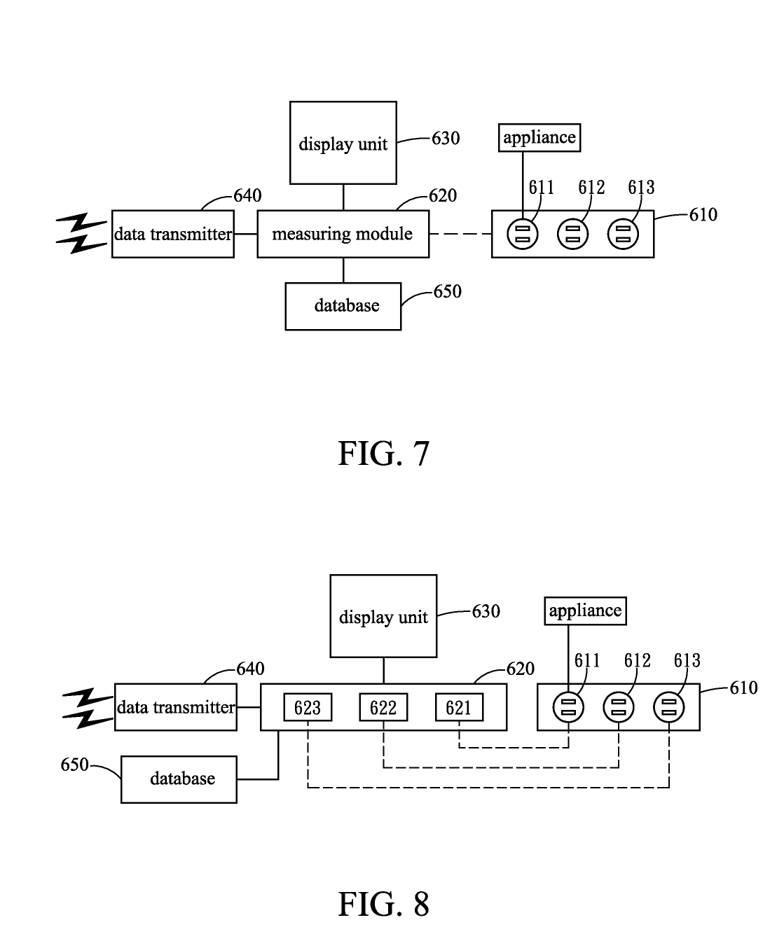

More than a power meter or a digital meter, the measuring unit 210 can be a socket apparatus with measuring functions. FIG. 7 illustrates an apparatus for monitoring residential appliances according to an embodiment of the present disclosure. The apparatus is composed of a socket module 610, a measuring module 620, a display unit 634, a data transmitter 640, and a database 650. According to the embodiment, the socket module 610 is used to supply at least one appliance with a power source, and may include a plurality of socket units (three socket units 611/612/613 as shown in FIG. 7, for example). The measuring module 620 is used to measure electrical data of at least one of the socket units 611/612/613. The data transmitter 640 is used to transmit the electrical data measured by the measuring module 610 wirelessly to the local data-processing unit 220. The display unit 630 is configured for displaying the electrical data measured by the measuring module 610. The database can record appliance information of the appliances in the residence, which can be set by their user or manufacturer. The measuring apparatus can also identify an appliance automatically by its electrical features, when the appliance is plugged in through the socket module 610. Further, the socket module 610 may include a plurality of socket units 611/612/613 and the measuring module 620 may include a plurality of measuring units 621/622/623, as shown in FIG. 8, wherein each measuring unit 621/622/623 is to measure the electrical data of each socket unit 611/612/613. The measured electrical data can also be uploaded to the local data-processing unit 220 wirelessly and to the display unit 630 for data display.

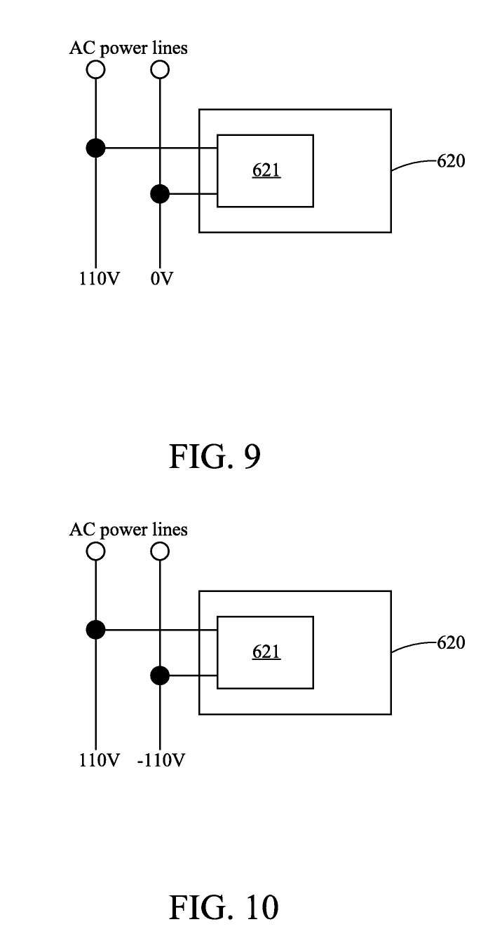

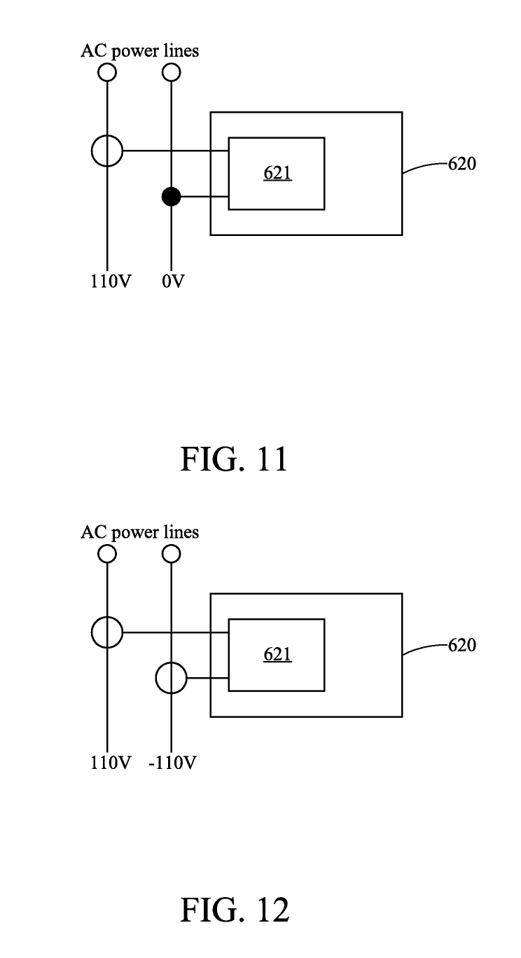

The measuring unit 210 or the measuring module 620 can be directly connected to AC power lines or electrically connected to the AC power line by using a retaining-ring sensor which surrounds and suspends around the AC power line. To measure the residential appliances operated at 110 volts, the measuring module 620 or the measuring unit 621 can be directly connected to AC power lines, one line with 110 volts and the other with 0 volt, to perform the measurement, as shown in FIG. 9. To measure the residential appliances operated at 220 volts, the measuring module 620 or the measuring unit 621 can be directly connected to AC power lines, one line with 110 volts and the other line with −110 volts, as shown in FIG. 10. On the other hand, in the measurement case of 110 volts, the measuring module 620 or the measuring unit 621 can be electrically connected to the AC power lines, one of which directly connected to AC power line of 0 volt and the other line of 110 volts suspended around by a retaining-ring sensor, as shown in FIG. 11. In the measurement case of 220 volts, the measuring module 620 or the measuring unit 621 can be electrically connected to the AC power lines, one line of 110 volts and the other line of −110 volts, respectively suspended around by two retaining-ring sensors, as shown in FIG. 12.

The local data-processing unit 220 includes a first database for recording appliance information of residential appliances which are commonly used or have ever been used in the residence; whereby the local data-processing unit 220 can compute the normalization of the electrical data and the variation of the normalized electrical data, and basically compare the variation to an electrical feature which is contained in the appliance information of the first database. Due to the fact that only appliance information of the residential appliances which are commonly used or have ever been used in the residence is required to be recorded in the local data-processing unit 220, a smaller capacity of storage is allowable therein, and the possibility of matching the measured electrical data to the electrical features is more than that of a database in the remote data-processing unit, which will be described in detail later. In case that a new appliance is operated for a first time, or somehow the operation of comparing or identifying fails in the local data-processing unit 220, an advanced comparison can be performed according to appliance information of more appliances which can be recorded in the other data-processing unit.

The appliance information in the first database can includes a basic information and an electrical feature of each appliance. The basic information can be selected from the group consisting of a brand name, an appliance type, a model number, and an operating mode, or can be composed of more than one element in the group. The electrical feature can be selected from the group consisting of a voltage, a real power, a normalization index of real power aP, a reactive power, a normalization index of reactive power aQ, a harmonic current of odd order, and a transient feature, or can be composed of more than one element in the group consisting of the real power, the reactive power, the harmonic current of odd order, and the transient feature. Wherein, the harmonic current of odd order can be a first-order harmonic current, a third-order harmonic current, or a fifth-order harmonic current, while the transient feature includes a transient waveform, a data type, a sampling rate, a sampling duration, and a sampling interval. Moreover, for the appliances which can be operated in several levels of magnitude, the appliance information of each appliance further comprises an magnitude-level feature which is selected from the group consisting of an magnitude level, a voltage, a real power, a normalization index of real power, a reactive power, a normalization index of reactive power, a harmonic current of odd order, and a transient feature of each operating magnitude level, or can be composed of more than one element in the group; wherein the transient feature includes a transient waveform, a data type, a sampling rate, a sampling duration, and a sampling interval.

Usually, after an appliance with several levels of magnitude is turned on and in use, it is a common behavior that people change its magnitude levels or switch its functional modes. Thus, when the measured electrical data change, the variation of the normalized electrical data can be compared to the difference of the magnitude-level features between the operating magnitude levels of the in-use appliance, before compared to the other electrical features of the appliance information. Whereby, the comparing operation can be speeded up further. Moreover, to update the electrical feature contained in appliance information of the first database in real time so as to increase the accuracy of the comparing work, the embodiment can further perform computing a time weighted average of the electrical features of the appliance, and updating the appliance information in the local data-processing unit with the time weighted average. Wherein, the appliance information may further include a predetermined threshold which is used to determine whether the appliance is of aging deterioration. For example, if the predetermined threshold is not substantially equal to the electrical feature corresponding to the deviation of the electrical data, it can be thought that performance of the appliance has been aged or deteriorated. Further, a second measuring unit (not shown) may be included in the embodiment, so as to compute and record power consumption curves of the appliance at different operating voltages. The curves or computed data of the appliance can then be performed with the normalization as the foregoing description of the normalization process, and recorded in the local data-processing unit 220. Also, the embodiment may include a classifying unit (not shown) therein, configured to classify the electrical features in the appliance information into groups according to an appliance attribution which includes a resistance mode, a motor mode, a pump mode, an electronic product mode, and a fluorescent light mode. Various modes of appliance may have their particular electrical features, respectively. To reduce the load of comparing with the appliance information in the whole database, if the mode or type of the possible causer appliance can be predicted, only the part of the database is needed to be compared one by one. Whereby, the comparing work can be speeded up further.

The remote data-processing unit 230, which is connected to the local data-processing unit 220, may include a second database for recording appliance information of various residential appliances with possibilities of being used. Operating similarly to the local data-processing unit 220, the remote data-processing unit 230 can be used to compare the variation the normalized electrical data to the electrical feature which is contained in the appliance information of the second database. Basically, it is expected according to the embodiment that appliance information of all existing residential appliances can be recorded in the second database, or once a newly developed or new model-number appliance enters into the market, the manufacturers can register the features or electric specification of the appliance to the second database, so that the remote data-processing unit 230 have complete appliance information of various appliances to facilitate the comparison works in the embodiment. The remote data-processing unit 230 can be regarded as a back-up to support the local data-processing unit 220. If the comparing or identifying operation fails in the local data-processing unit 220, the measured electrical data may be forwarded to the remote data-processing unit 230 for a more complete comparison between the electrical features and the electrical data. If the comparison operation is passed, the remote data-processing unit 230 may re-transmit the electrical features of the appliance to the local data-processing unit 220, so as to increase the appliance information in the first database and show the comparison result on the monitor display (not shown) corresponding to the local data-processing unit 220. On the other hand, if the comparison operation is failed, the remote data-processing unit 230 may also re-transmit the electrical features of the appliance to the local data-processing unit 220, and show the result on the monitor display.

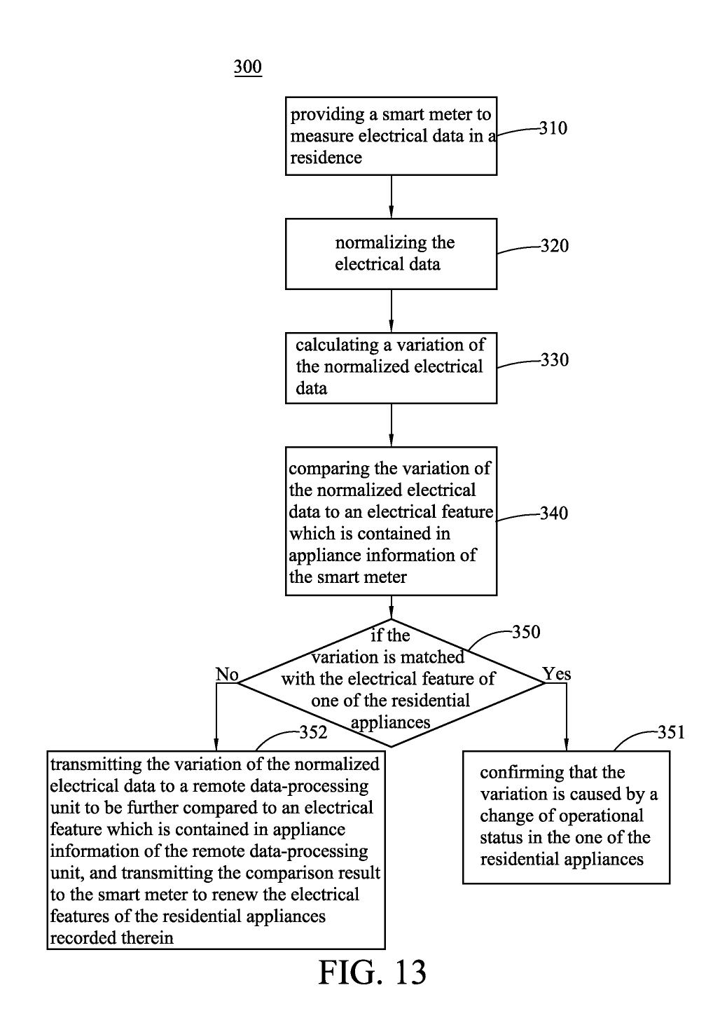

The measuring unit in the foregoing embodiments can also be operable to advanced functions, such as data processing, database, and displaying. For example, a smart meter, which has multiple functions of measuring electrical data, calibrating electrical parameters, extracting electrical features of appliance, and comparing the electrical features, can be used to replace the measuring unit 210 and the local data-processing unit 220 in the foregoing embodiments. Please refer to FIG. 13, which is a schematic flowchart showing the procedure of a method 300 for monitoring residential appliances according to a third embodiment of the present disclosure. The method 300 comprises the following steps. In Step 310, a smart meter is provided for measuring electrical data in a residence. In Step 320, the measured electrical data are normalized. In Step 330, a variation of the normalized electrical data is calculated. In Step 340, the variation of the normalized electrical data is compared to an electrical feature which is contained in appliance information of the smart meter. The succeeding step follows according to the comparison result in the Step 350, which matches the variation with the electrical features of the residential appliances. If the variation is matched with the electrical feature of one of the residential appliances, it is confirmed, in Step 351, that the variation is caused by a change of operational status in the one of the residential appliances. Otherwise, it goes to Step 352, in which the variation is transmitted to a remote data-processing unit to be further compared to an electrical feature which is contained in appliance information of the remote data-processing unit, and the comparison result may be transmitted back to the local data-processing unit to renew the electrical features of the residential appliances recorded in the smart meter. The electrical data measured in the Step 310 at least include a voltage, a real power, and a reactive power used in the residence, and the electrical data can be normalized according to the measured voltage. If the electrical data are measured to have a change, the smart meter will perform the computation of the variation and the other procedures. Wherein, the other procedures according to this embodiment are basically the same as the corresponding steps in the first embodiment, and thus can be referred to the descriptions thereof and are not restated here.

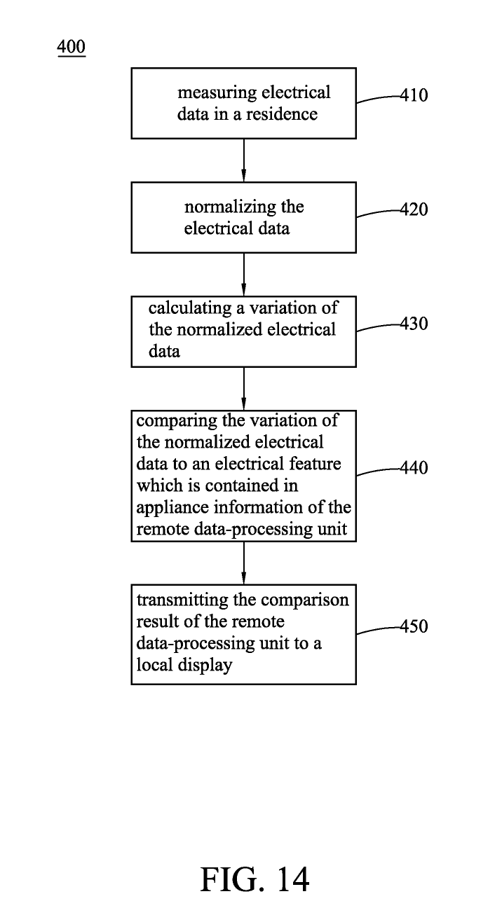

On the other hand, if the remote data-processing unit 230 is with a powerful capacity of data processing and a high data rate of transmission to the measuring unit 210, the local data-processing unit 220 may be omitted. In the following embodiment, the measuring unit is an ordinary powermeter only with basic functions of measuring electrical data, while the functions of calibrating electrical parameters, extracting electrical features of appliance, and comparing the electrical features can be executed by a remote data-processing unit 230 with a database. Please refer to FIG. 14, which is a schematic flowchart showing the procedure of a method 400 for monitoring residential appliances according to a fourth embodiment of the present disclosure. The method 400 comprises the following steps. In Step 410, electrical data are measured in a residence and transmitted to a remote data-processing unit. In Step 420, the electrical data are normalized. In Step 430, a variation of the normalized electrical data is calculated. In Step 440, the variation of the normalized electrical data is compared to an electrical feature which is contained in appliance information of the remote data-processing unit. In Step 450, the comparison result can be transmitted back to a local display and shown thereon. The electrical data measured in the Step 410 at least include a voltage, a real power, and a reactive power used in the residence, and the electrical data can be normalized according to the measured voltage. If the electrical data are measured to be changed, the remote data-processing unit will perform the computation of the variation and the other procedures. Wherein, the other procedures according to this embodiment are basically the same as the corresponding steps in the first embodiment, and thus can be referred to the descriptions thereof and are not restated here.

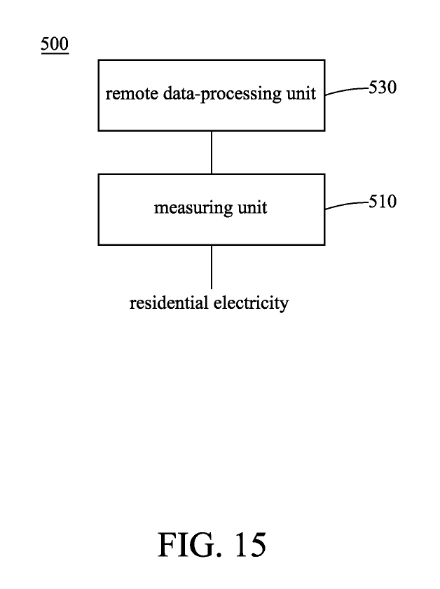

The foregoing method for monitoring residential appliances according to the fourth embodiment can be implemented in the following embodiment. Please refer to FIG. 15, which is a block diagram showing a system for monitoring residential appliances according to a second embodiment of the present disclosure. The system 500 includes a measuring unit 510 and a remote data-processing unit 530. The measuring unit 510, used to measure electrical data in a residence, can be a power meter or a digital meter equipped therein. The measured electrical data may be then be uploaded to the remote data-processing unit 530. According to this embodiment, the electrical data of a whole residence are measured in order to identify the causer appliance which switches its status of operation, and to further estimate its usage duration and cost, which was implemented by providing every single appliance with a measuring unit or a power meter in the prior art. In this embodiment, however, the measured electrical data can be compared with the electrical features of the appliances in the back-end or remote data processing unit, so as to determine the causer appliance and get its usage condition and electrical data automatically in real time. The foregoing electrical data are mainly composed of a voltage, a real power, and a reactive power, so that they can be normalized and compared to the electrical features of the appliances according to the measured voltage in a first stage. If the comparison fails, the electrical data can include a harmonic current of odd order for further comparison to the appliance features in a second stage. If the comparison still fails, the electrical data can also include a transient signal, which may be of current, real power, reactive power, or apparent power, for further comparison to the appliance features in a third stage.

The remote data-processing unit 530, which is connected to the measuring unit 510, may include a third database for recording appliance information of various residential appliances with possibilities of being used. The remote data-processing unit 230 can be used to compare the variation the normalized electrical data to the electrical feature which is contained in the appliance information of the third database. Basically, it is expected according to the embodiment that appliance information of all existing residential appliances can be recorded in the third database, or once a newly developed or new model-number appliance enters into the market, the manufacturers can register the features or electric specification of the appliance to the third database, so that the remote data-processing unit 530 have complete appliance information of various appliances to facilitate the comparison works in this embodiment. The comparison result can be transmitted back to a local display and shown thereon. Wherein, the other details according to this embodiment are basically the same as the corresponding parts in the second embodiment, and thus can be referred to the descriptions thereof and are not restated here.

As an appliance is used for a long time, the electrical features thereof may change gradually due to user behaviors or power-supply conditions. This may lead to misjudgment in the measure system. To solve the problem of machine aging, to increase the accuracy of identification, and to provide warning messages for renewing an out-of-condition appliance, a mechanism to adjust electrical features of appliance adaptively is developed in the embodiments. The electrical feature which is contained in appliance information of the local data-processing unit can be recorded therein whenever the appliance is turned on. The electrical feature is multiplied by a weight index, so as to renew the database in the local data-processing unit. The time weighted average of the electrical features of the appliance can be calculated by the following equation:

$${P}_{update} = \frac{{\sum }_{i = 1}^{w} {a}_{i} {P}_{n + 1 - w}}{{\sum }_{i = 1}^{w} {a}_{i}}$$

Wherein, Pₙ denotes the electrical parameter of the n-th turning-on, aᵢ denotes the weight for the weighted average, and w denotes the count of the past data. For example, if w=3 and a₁=a₂=a_{w}, the time weighted average of the electrical features in the last three years can be the feature average, which is then used to renew the electrical feature in the database of the data-processing unit. Also, a predetermined threshold may be used to determine that the appliance is of aging deterioration and thus transmit a warning signal that the appliance is not in condition, if the predetermined threshold is not substantially equal to the electrical feature corresponding to the deviation of the electrical data. Consequently, even when an appliance is under the aging deterioration, misjudgment would not occur in the system according to the embodiments.

With respect to the foregoing description, it is to be realized that the optimum dimensional relationships for the parts of the disclosure, to include variations in size, materials, shape, form, function and manner of operation, assembly and use, are deemed readily apparent and obvious to one skilled in the art, and all equivalent relationships to those illustrated in the drawings and described in the specification are intended to be encompassed by the present disclosure.

What is claimed is:

1. A method for monitoring residential appliances comprising the following steps:
measuring electrical data in a residence and transmitting the electrical data to a local data-processing unit, the electrical data at least containing a voltage, a real power, and a reactive power;
normalizing the electrical data according to the voltage;
calculating a variation of the normalized electrical data when the electrical data change; and
comparing the variation of the normalized electrical data to an electrical feature which is contained in appliance information of the local data-processing unit, so as to determine the appliance which causes the variation of the electrical data.

2. The method of claim 1, further comprising the steps of
if the variation of the normalized electrical data is matched with the electrical feature of one of the residential appliances, confirming that the variation is caused by a change of operational status in the one of the residential appliances; otherwise, transmitting the variation of the normalized electrical data to a remote data-processing unit to be further compared to an electrical feature which is contained in appliance information of the remote data-processing unit; and
transmitting the comparison result of the remote data-processing unit to the local data-processing unit to renew the electrical features of the residential appliances recorded in the local data-processing unit.

3. The method of claim 2, wherein the change of operational status in the residential appliances is selected from the group consisting of turning on, turning off, magnitude-level switching, and function switching.

4. The method of claim 1, wherein the electrical data further comprises a harmonic current of odd order.

5. The method of claim 1, wherein the electrical data further comprises
a transient signal which is of current, real power, reactive power, or apparent power.

6. The method of claim 1, wherein the appliance information of each appliance comprises
a basic information which is selected from the group consisting of a brand name, an appliance type, a model number, and an operating mode; and
an electrical feature which is selected from the group consisting of a voltage, a real power, a normalization index of real power, a reactive power, a normalization index of reactive power, a harmonic current of odd order, and a transient feature;
wherein the transient feature includes a transient waveform, a data type, a sampling rate, a sampling duration, and a sampling interval.

7. The method of claim 6, wherein the appliance information of each appliance further comprises
an magnitude-level feature which is selected from the group consisting of an magnitude level, a voltage, a real power, a normalization index of real power, a reactive power, a normalization index of reactive power, a harmonic current of odd order, and a transient feature of each operating magnitude level, wherein the transient feature includes a transient waveform, a data type, a sampling rate, a sampling duration, and a sampling interval.

8. The method of claim 7, before comparing the variation of the normalized electrical data to the electrical features of the appliance information when the electrical data change, the method further comprising the step of
comparing the variation of the normalized electrical data to the difference of the magnitude-level features between the operating magnitude levels of an in-use appliance.

9. The method of claim 1, wherein the electrical features in the appliance information are classified into groups according to an appliance attribution which includes a resistance mode, a motor mode, a pump mode, an electronic product mode, and a fluorescent light mode.

10. The method of claim 2, wherein the appliance information recorded in the remote data-processing unit is set by a user or manufacturer of the residential appliances.

11. The method of claim 10, wherein the appliance information is set in a way that the manufacturer of the residential appliances uploads the appliance information to the remote data-processing unit, or that the remote data-processing unit asks the manufacturer to provide the appliance information.

12. The method of claim 1, further comprising the step of
computing and recording power consumption curves of the appliance at different operating voltages.

13. The method of claim 1, further comprising the steps of
computing a time weighted average of the electrical features of the appliance; and
updating the appliance information in the local data-processing unit with the time weighted average.

14. The method of claim 13, wherein the appliance information further comprising
a predetermined threshold which is used to determine that the appliance is of aging deterioration, if the predetermined threshold is not substantially equal to the electrical feature corresponding to the deviation of the electrical data.

15. A method for monitoring residential appliances comprising the following steps:
providing a smart meter, which at least has functions of data processing, database, and displaying;
measuring electrical data in a residence, the electrical data at least containing a voltage, a real power, and a reactive power;
normalizing the electrical data according to the voltage;
calculating a variation of the normalized electrical data when the electrical data change; and
comparing the variation of the normalized electrical data to an electrical feature which is contained in appliance information of the smart meter, so as to determine the appliance which causes the variation of the electrical data.

16. The method of claim 15, further comprising the steps of
if the variation of the normalized electrical data is matched with the electrical feature of one of the residential appliances, confirming that the variation is caused by a change of operational status in the one of the residential appliances; otherwise, transmitting the variation of the normalized electrical data to a remote data-processing unit to be further compared to an electrical feature which is contained in appliance information of the remote data-processing unit; and
transmitting the comparison result of the remote data-processing unit to the smart meter to renew the electrical features of the residential appliances recorded in the smart meter.

17. The method of claim 16, wherein the change of operational status in the residential appliances is selected from the group consisting of turning on, turning off, magnitude-level switching, and function switching.

18. The method of claim 15, wherein the electrical data further comprises a harmonic current of odd order.

19. The method of claim 15, wherein the electrical data further comprises
a transient signal which is of current, real power, reactive power, or apparent power.

20. The method of claim 15, wherein the appliance information of each appliance comprises
a basic information which is selected from the group consisting of a brand name, an appliance type, a model number, and an operating mode; and
an electrical feature which is selected from the group consisting of a voltage, a real power, a normalization index of real power, a reactive power, a normalization index of reactive power, a harmonic current of odd order, and a transient feature;
wherein the transient feature includes a transient waveform, a data type, a sampling rate, a sampling duration, and a sampling interval.

21. The method of claim 20, wherein the appliance information of each appliance further comprises
an magnitude-level feature which is selected from the group consisting of an magnitude level, a voltage, a real power, a normalization index of real power, a reactive power, a normalization index of reactive power, a harmonic current of odd order, and a transient feature of each operating magnitude level, wherein the transient feature includes a transient waveform, a data type, a sampling rate, a sampling duration, and a sampling interval.

22. The method of claim 21, before comparing the variation of the normalized electrical data to the electrical features of the appliance information when the electrical data change, the method further comprising the step of
comparing the variation of the normalized electrical data to the difference of the magnitude-level features between the operating magnitude levels of an in-use appliance.

23. The method of claim 15, wherein the electrical features in the appliance information are classified into groups according to an appliance attribution which includes a resistance mode, a motor mode, a pump mode, an electronic product mode, and a fluorescent light mode.

24. The method of claim 16, wherein the appliance information recorded in the remote data-processing unit is set by a user or manufacturer of the residential appliances.

25. The method of claim 24, wherein the appliance information is set in a way that the manufacturer of the residential appliances uploads the appliance information to the remote data-processing unit, or that the remote data-processing unit asks the manufacturer to provide the appliance information.

26. The method of claim 15, further comprising the step of computing and recording power consumption curves of the appliance at different operating voltages.

27. The method of claim 15, further comprising the steps of
computing a time weighted average of the electrical features of the appliance; and
updating the appliance information in the smart meter with the time weighted average.

28. The method of claim 27, wherein the appliance information further comprising
a predetermined threshold which is used to determine that the appliance is of aging deterioration, if the predetermined threshold is not substantially equal to the electrical feature corresponding to the deviation of the electrical data.

29. A method for monitoring residential appliances comprising the following steps:
measuring electrical data in a residence and transmitting the electrical data to a remote data-processing unit, the electrical data at least containing a voltage, a real power, and a reactive power;
normalizing the electrical data according to the voltage;
calculating a variation of the normalized electrical data when the electrical data change;
comparing the variation of the normalized electrical data to an electrical feature which is contained in appliance information of the remote data-processing unit, so as to determine the appliance which causes the variation of the electrical data; and
transmitting the comparison result of the remote data-processing unit to a local display.

30. The method of claim 29, wherein the electrical data further comprises a harmonic current of odd order.

31. The method of claim 29, wherein the electrical data further comprises
a transient signal which is of current, real power, reactive power, or apparent power.

32. The method of claim 29, wherein the appliance information of each appliance comprises
a basic information which is selected from the group consisting of a brand name, an appliance type, a model number, and an operating mode; and
an electrical feature which is selected from the group consisting of a voltage, a real power, a normalization index of real power, a reactive power, a normalization index of reactive power, a harmonic current of odd order, and a transient feature;
wherein the transient feature includes a transient waveform, a data type, a sampling rate, a sampling duration, and a sampling interval.

33. The method of claim 32, wherein the appliance information of each appliance further comprises
an magnitude-level feature which is selected from the group consisting of an magnitude level, a voltage, a real power, a normalization index of real power, a reactive power, a normalization index of reactive power, a harmonic current of odd order, and a transient feature of each operating magnitude level, wherein the transient feature includes a transient waveform, a data type, a sampling rate, a sampling duration, and a sampling interval.

34. The method of claim 33, before comparing the variation of the normalized electrical data to the electrical features of the appliance information when the electrical data change, the method further comprising the step of
comparing the variation of the normalized electrical data to the difference of the magnitude-level features between the operating magnitude levels of an in-use appliance.

35. The method of claim 29, wherein the electrical features in the appliance information are classified into groups according to an appliance attribution which includes a resistance mode, a motor mode, a pump mode, an electronic product mode, and a fluorescent light mode.

36. The method of claim 29, wherein the appliance information recorded in the remote data-processing unit is set by a user or manufacturer of the residential appliances.

37. The method of claim 36, wherein the appliance information is set in a way that the manufacturer of the residential appliances uploads the appliance information to the remote data-processing unit, or that the remote data-processing unit asks the manufacturer to provide the appliance information.

38. The method of claim 29, further comprising the step of
computing and recording power consumption curves of the appliance at different operating voltages.

39. The method of claim 29, further comprising the steps of
computing a time weighted average of the electrical features of the appliance; and
updating the appliance information in the remote data-processing unit with the time weighted average.

40. The method of claim 39, wherein the appliance information further comprising
a predetermined threshold which is used to determine that the appliance is of aging deterioration, if the predetermined threshold is not substantially equal to the electrical feature corresponding to the deviation of the electrical data.

41. A system for monitoring residential appliances comprising:
a measuring unit provided for measuring electrical data in a residence; and
a local data-processing unit connected to the measuring unit, comprising a first database for recording appliance information of at least one residential appliance, and provided for normalizing the electrical data, computing a variation of the normalized electrical data, and comparing the variation of the normalized electrical data to an electrical feature which is contained in the appliance information of the first database, so as to determine the appliance which causes the variation of the electrical data.

42. The system of claim 41, further comprising
a remote data-processing unit connected to the local data-processing unit, comprising a second database for recording appliance information of various residential appliances with a possibility of being used, and provided for comparing the variation the normalized electrical data to an electrical feature which is contained in the appliance information of the second database.

43. The system of claim 41, wherein the electrical data comprises a voltage, a real power, and a reactive power.

44. The system of claim 41, wherein the electrical data comprises a harmonic current of odd order.

45. The system of claim 41, wherein the electrical data comprises a transient signal which is of current, real power, reactive power, or apparent power.

46. The system of claim 41, wherein the appliance information of each appliance comprises
a basic information which is selected from the group consisting of a brand name, an appliance type, a model number, and an operating mode; and
an electrical feature which is selected from the group consisting of a voltage, a real power, a normalization index of real power, a reactive power, a normalization index of reactive power, a harmonic current of odd order, and a transient feature;
wherein the transient feature includes a transient waveform, a data type, a sampling rate, a sampling duration, and a sampling interval.

47. The system of claim 46, wherein the appliance information of each further comprises
an magnitude-level feature which is selected from the group consisting of an magnitude level, a voltage, a real power, a normalization index of real power, a reactive power, a normalization index of reactive power, a harmonic current of odd order, and a transient feature of each operating magnitude level, wherein the transient feature includes a transient waveform, a data type, a sampling rate, a sampling duration, and a sampling interval.

48. The system of claim 47, before comparing the variation of the normalized electrical data to the electrical features of the appliance information when the electrical data change, the local data-processing unit comparing the variation of the normalized electrical data to the difference of the magnitude-level features between the operating magnitude levels of an in-use appliance.

49. The system of claim 41, further comprising
a classifying unit classifying the electrical features in the appliance information into groups according to an appliance attribution which includes a resistance mode, a motor mode, a pump mode, an electronic product mode, and a fluorescent light mode.

50. The system of claim 42, wherein the appliance information recorded in the remote data-processing unit is set by a user or manufacturer of the residential appliances.

51. The system of claim 50, wherein the appliance information is set in a way that the manufacturer of the residential appliances uploads the appliance information to the remote data-processing unit, or that the remote data-processing unit asks the manufacturer to provide the appliance information.

52. The system of claim 41, further comprising
a second measuring unit computing and recording power consumption curves of the appliance at different operating voltages.

53. The system of claim 41, wherein the local data-processing unit further computing a time weighted average of the electrical features of the appliance, and updates the appliance information of the first database with the time weighted average.

54. The system of claim 53, wherein the appliance information further comprising a predetermined threshold which is used to determine that the appliance is of aging deterioration, if the predetermined threshold is not substantially equal to the electrical feature corresponding to the deviation of the electrical data.

55. An apparatus for monitoring residential appliances, the apparatus comprising:
a socket module provided for supplying at least one appliance with a power source;
a measuring module measuring electrical data of the socket module;
a data transmitter wirelessly transmitting the electrical data measured by the measuring module;
a database recording appliance information of the at least one appliance; and
a display unit displaying the electrical data measured by the measuring module.

56. The apparatus of claim 55, wherein the socket module comprises a plurality of socket units and the measuring module comprises a plurality of measuring units, each measuring unit measuring the electrical data of each socket unit.

57. The apparatus of claim 55, wherein the appliance information of the at least one residential appliance recorded in the database is set by a user or manufacturer of the appliance.

58. The apparatus of claim 55, wherein the measuring module is directly connected to AC power lines of the system.

59. The apparatus of claim 55, wherein the measuring module is electrically connected to AC power lines of the system by using a retaining-ring sensor which surrounds the AC power lines.

60. A system for monitoring residential appliances comprising:
a measuring unit provided for measuring electrical data in a residence; and
a remote data-processing unit connected to the measuring unit, comprising a second database for recording appliance information of at least one residential appliance, and provided for normalizing the electrical data, computing a variation of the normalized electrical data, and comparing the variation of the normalized electrical data to an electrical feature which is contained in the appliance information of the second database, so as to determine the appliance which causes the variation of the electrical data.

61. The system of claim 60, wherein the electrical data comprises a voltage, a real power, and a reactive power.

62. The system of claim 60, wherein the electrical data comprises a harmonic current of odd order.

63. The system of claim 60, wherein the electrical data comprises a transient signal which is of current, real power, reactive power, or apparent power.

64. The system of claim 60, wherein the appliance information of each appliance comprises
a basic information which is selected from the group consisting of a brand name, an appliance type, a model number, and an operating mode; and
an electrical feature which is selected from the group consisting of a voltage, a real power, a normalization index of real power, a reactive power, a normalization index of reactive power, a harmonic current of odd order, and a transient feature;
wherein the transient feature includes a transient waveform, a data type, a sampling rate, a sampling duration, and a sampling interval.

65. The system of claim 64, wherein the appliance information of each further comprises
an magnitude-level feature which is selected from the group consisting of an magnitude level, a voltage, a real power, a normalization index of real power, a reactive power, a normalization index of reactive power, a harmonic current of odd order, and a transient feature of each operating magnitude level, wherein the transient feature includes a transient waveform, a data type, a sampling rate, a sampling duration, and a sampling interval.

66. The system of claim 65, before comparing the variation of the normalized electrical data to the electrical features of the appliance information when the electrical data change, the remote data-processing unit comparing the variation of the normalized electrical data to the difference of the magnitude-level features between the operating magnitude levels of an in-use appliance.

67. The system of claim 60, further comprising
a classifying unit classifying the electrical features in the appliance information into groups according to an appliance attribution which includes a resistance mode, a motor mode, a pump mode, an electronic product mode, and a fluorescent light mode.

68. The system of claim 60, wherein the appliance information recorded in the remote data-processing unit is set by a user or manufacturer of the residential appliances.

69. The system of claim 68, wherein the appliance information is set in a way that the manufacturer of the residential appliances uploads the appliance information to the remote data-processing unit, or that the remote data-processing unit asks the manufacturer to provide the appliance information.

70. The system of claim 60, further comprising
a second measuring unit computing and recording power consumption curves of the appliance at different operating voltages.

71. The system of claim 60, wherein the remote data-processing unit further computing a time weighted average of the electrical features of the appliance, and updates the appliance information of the second database with the time weighted average.

72. The system of claim 71, wherein the appliance information further comprising a predetermined threshold which is used to determine that the appliance is of aging deterioration, if the predetermined threshold is not substantially equal to the electrical feature corresponding to the deviation of the electrical data.
